(19) United States
(12) Patent Application Publication
(10) Pub. No.: US 2004/0128112 A1
(43) Pub. Date: Jul. 1, 2004

(54) System and method for holistic management of risk and return

(76) Inventors: Howard W. Mikytuck JR., Glen Allen, VA (US); Mark William Griffin, New Canaan, CT (US)

Correspondence Address: HUNTON & WILLIAMS LLP, INTELLECTUAL PROPERTY DEPARTMENT, 1900 K STREET, N.W., SUITE 1200, WASHINGTON, DC, 20006-1109, US

(21) Appl. No.: 10/318,192

(22) Filed: Dec. 13, 2002

(51) Int. Cl. H03F 1/26

(52) U.S. Cl. 702/190

(57) ABSTRACT

The present invention provides a system and method for data analysis that enables a user, among other things, to assess a particular product's relative risk and potential return, quantify the impact of individual risk drivers, determine a range of potential outcomes for a given scenario, monitor financial progress over time, identify critical factors for success or failure in a situation, measure the diversification impact of buying or selling a block of businesses, and perform other analysis functions. Disclosed embodiments include a processor implemented method for evaluating risk and return by determining one or more risk drivers, determining a forecast model based, at least in part, upon the one or more risk drivers, enabling a processor to run a simulation using the forecast model and the one or more risk drivers and generating one or more output displays that enable an evaluation of risk and return based, at least in part, upon the simulation.

### BACKGROUND OF THE INVENTION

This invention relates to a system and method for holistic management of risk and return associated with one or more products offered through one or more sales channels. Embodiments of the invention relate to a system and method for quantifying one or more stochastic risk drivers to enable calculation of revenue by sales channel.

Existing systems for evaluation of risk and return typically implement static point estimates for dynamic volatility measures. One drawback with these existing approaches is that static point estimates do not always yield an accurate and reliable picture of volatility effects.

In addition, existing systems lack the tools to enable a comprehensive understanding of the effects of risk factors on the volatility of returns as measured by Return on Equity (ROE). For example, existing systems lack a mechanism for computing a deviation reference. Therefore, in these type systems it is difficult to know whether any experienced volatility was expected or abnormal. Time and effort may be wasted chasing many normal volatility movements by incorrectly thinking they are abnormal. Other drawbacks also exist.

### SUMMARY OF THE INVENTION

The present invention provides a system and method for data analysis that enables a user, among other things, to assess a particular product's relative risk and potential return, quantify the impact of individual risk drivers, determine a range of potential outcomes for a given scenario, monitor financial progress over time, identify critical factors for success or failure in a situation, measure the diversification impact of buying or selling a block of businesses, and perform other analysis functions. For example, some embodiments of the invention enable a user to assess the affect of particular risk drivers (e.g., interest rate, lapse rate, etc.) on the potential return of a given product (e.g., a guaranteed investment contract (GIC), annuity contract, etc.). In addition, the invention enables a user to evaluate the affect of a given product (e.g., GIC, annuity, mutual fund, etc.) or group of products on the overall performance (e.g., net income, profitability, etc.) of a given enterprise (e.g., company, division, subsidiary, etc.). Other applications are possible.

### BRIEF DESCRIPTION OF THE FIGURES

FIG. 1 is a schematic of the overall system according to an embodiment of the invention.

FIG. 2 is a schematic flow diagram illustrating an evaluation process according to an embodiment of the invention.

FIG. 3 is a schematic of a relational income statement input interface according to an embodiment of the invention.

FIGS. 4A and 4B are examples of possible output from a simulation of an evaluation of the risks and return for a guaranteed investment contract (GIC) according to an embodiment of the invention.

FIG. 5A is an example of two output displays for two separate products that may serve as input for a company wide evaluation of risks and return according to embodiments of the invention.

FIG. 5B is an example of an output display showing combined affects on company net income for the two products shown in FIG. 5A

FIG. 6 is an example of another possible output display according to embodiments of the invention.

FIG. 7 is an example of an output display for a simulation according to an embodiment of the invention.

FIG. 8 is an example of a display output that incorporates a retention limit risk driver calculation into the net income projection according to an embodiment of the invention.

FIG. 9 is an example of different portfolio product mixes according to some embodiments of the invention.

FIG. 10 is a is an example of a plot of an efficient frontier according to some embodiments of the invention.

### DETAILED DESCRIPTION OF THE INVENTION

Reference will now be made in detail to the present preferred embodiments of the invention, examples of which are illustrated in the accompanying drawings in which like reference characters refer to corresponding elements.

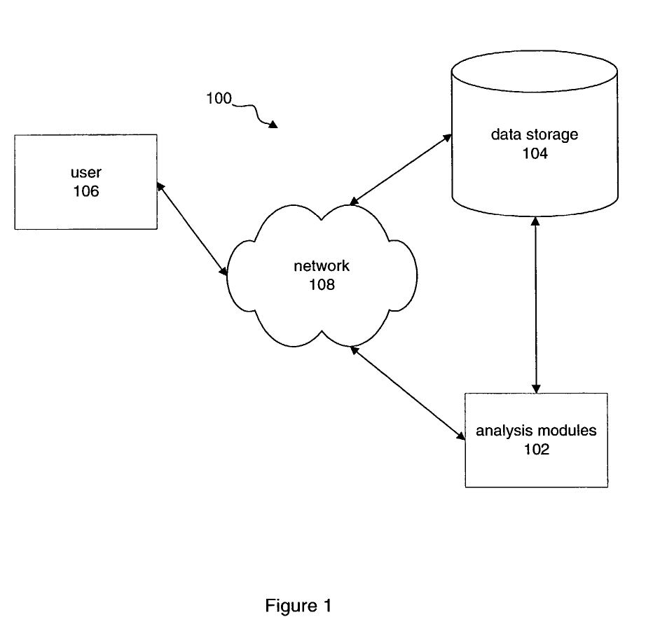

FIG. 1 is a schematic illustration of the overall system 100 according to an embodiment of the invention. As shown, system 100 may comprise a number of analysis modules 102. Analysis modules 102 may be implemented by any suitable processor device (not shown). For example, analysis modules 102 may be implemented by a personal computer (PC), a main frame computer, a desktop workstation, a laptop, palmtop, personal digital assistant, or other suitable device.

In some embodiments, analysis modules 102 may comprise one or more modules, or parts of modules, distributed over one or more processor devices. For example, some of analysis modules 102 may be implemented at a client side device (e.g., a PC) and other modules may be implemented at a server. Other configurations are also possible.

Analysis modules 102 may communicate with data storage 104. Data storage 104 may comprise any suitable system for storing data that may be used during the implementation of analysis modules 102. For example, data storage 104 may comprise a suitable database such as Microsoft Access® or Excel® along with any A Programming Language (APL) system interface. In some embodiments, data storage 104 may comprise a distributed system of storage devices. It is also possible for data storage 104 to comprise a component of the device implementing analysis modules 102 (i.e., data storage 104 may comprise a hard disk storage location of a PC that implements analysis modules 102). Other configurations are also possible.

One or more users 106 may access the analysis modules 102. In some embodiments, users may be allowed to perform certain operations according to a predetermined access level. For example, a user 106 with administrative rights may be allowed to configure analysis modules 102 whereas another user 106 with limited rights may be allowed only to access results of a given analysis module 102 calculation.

In some embodiments, users 106 may access analysis modules 102 via a suitable network 108. For example, users 106 may access analysis modules 102 over a LAN, WAN, intranet, the Internet, a wireless network, a cellular network, a satellite network, or some other suitable network. In addition, some embodiments of the invention, enable users 106 to communicate with data storage 104 over network 108. Other configurations (e.g., such as a standalone configuration wherein user access, analysis modules and data storage are provided in a single device) are also possible.

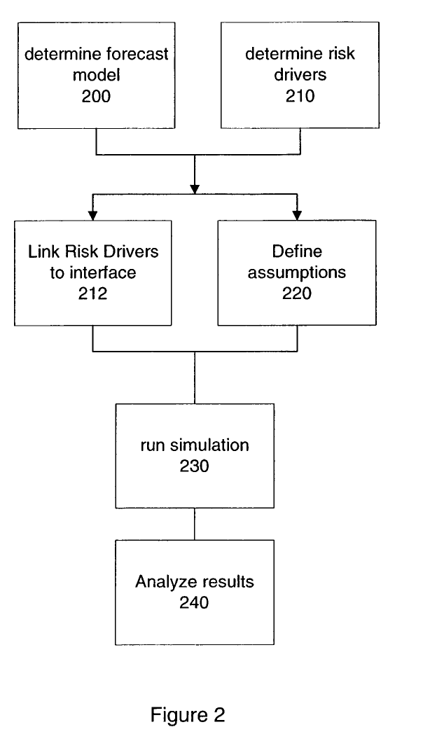

FIG. 2 is a flow diagram illustrating an evaluation process according to an embodiment of the invention. As shown at 200, the process may initiate by determining forecast model level. A forecast model level may comprise some function or formula to quantify net income or ROE as a function of some risk drivers (i.e., interest, mortality, loss rate, etc.) Once the distribution about the risk drivers are determined (e.g., through analytics, distribution fitting, such as, Chi-Square, Kolmogorov-Smirnov, Anderson Darling, Normality testing, or expert experience) then, through Monte Carlo or other simulation, the relationship of Risk Drivers to Net Income or ROE may also be developed.

As shown at 210, the invention may also comprise determining one or more risk drivers. The particular risk drivers may vary according to forecast model, product, type of analysis and other factors. In general, risk drivers may comprise those factors that, when varied, may affect the outcome of a calculation using a given forecast model. For example, risk drivers may include: lapse rate of an insurance policy, mortality rate of insurance policy holders, morbidity rate of insurance policy holders (i.e., long term illness), production rates, premiums (e.g., dollar or other cash amounts), market risk (a quantification of volatility), rate of return on investments, termination rate, loss ratio (e.g., actual to expected), spread (e.g., earned rate—credit rate), competition rate, production, first year premium, renewal premium, inflows, outflows, market appreciation/depreciation, credit rate risk (e.g., ability to pay back debts), default risk and other factors.

The manner in which risk factors are determined may also vary according to a number of factors. For example, performance history of a product may be used to determine risk factors. Factors such as lapse rate, termination rate, inflows, outflows, etc. may be determined from evaluation of prior performance for a given product. Other uses of performance history are also possible.

Other approaches to determining risk factors may include culling factors from industry benchmarking reports, modeling macro economic indicators, obtaining expert opinion, surveying personnel to form a consensus, and through other group decision making techniques. Other methods may include, but are not limited to, utilizing published industry tables (i.e. Mortality) and performing statistical analysis on historical drivers. The analysis performed may be a form of segmentation such as CHAID (Chi-Squared Automatic Interaction Detector). CHAID segments a set of drivers into homogeneous populations that differ significantly from other groups by a designated criterion. In addition to the methods mentioned, reverse engineering the Product Income State is also possible through historical analysis. This may consist of fitting distributions to the historical drivers (e.g., those that show volatility year over year).

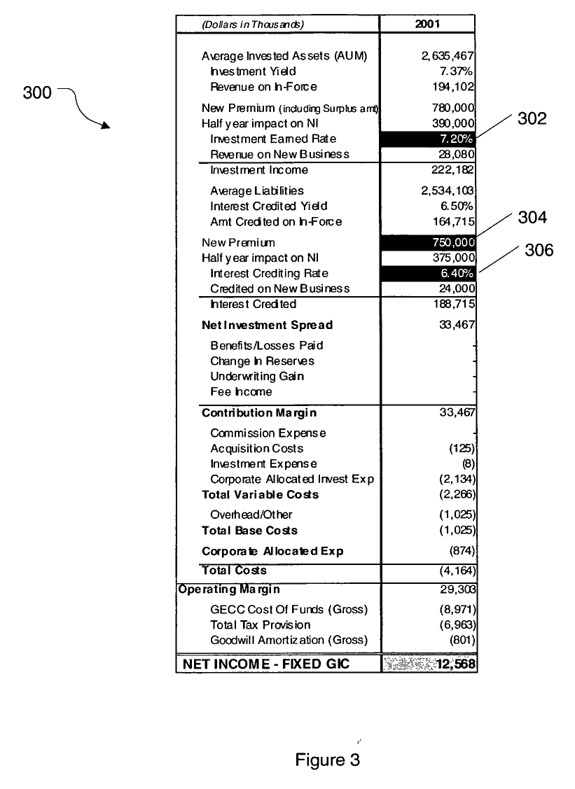

As indicated at 212, some embodiments of the invention provide for linking the risk drivers (e.g., as determined at 210) to an interface (e.g., such as a financial statement 300 shown in FIG. 3). Linking risk drivers may comprise any suitable method for associating portions of the interface (e.g., financial statement 300) with certain risk drivers.

For example, the highlighted fields shown in FIG. 3 may represent fields that are linked to certain risk drivers (e.g., an investment earned rate 302, new premiums 304, and an interest crediting rate 306). In some embodiments, changes to, or calculations performed with, the risk drivers may be automatically updated in the linked fields of the interface. As discussed herein, the particular risk drivers may change depending upon the particular risk—return scenario being evaluated.

As indicated at 220 in FIG. 2, the invention may also comprise defining assumptions related to the forecast model or risk drivers. In some embodiments, assumptions may be associated with one or more of the risk drivers. For example, certain parameters, ranges of values, or other variables may be associated with a given risk driver (e.g., a policy holder retention rate will be between 0% and 100%, mortality rate will follow a bell-shaped distribution, share price will be between $1 and $5, etc.). At 220 a user may input or otherwise adjust the assumptions associated with one or more risk drivers. These assumption may be fitted using statistical methods and techniques, such as, normality testing, chi-square testing and other techniques.

As indicated at 230, a simulation may be run using previously input forecast model, risk drivers and assumptions. Simulations may be run using any suitable software module or other appropriate data processing system. For example, Crystal Ball® software by Decisoneering®, VAR® Value at risk by Palisade®, and others may be used to run simulations. In some embodiments, simulations may be run using a Monte Carlo simulation, Quasi-Monte Carlo simulations, quantile regression simulations, or other appropriate simulation.

As indicated at 240, the invention may also comprise analyzing results of the simulations performed at 230. Any appropriate displays, graphs, charts and other analysis tools may be used. The following discussion provides some examples of possible analysis tools.

FIG. 3 is an example of Relational Income Statement Input interface 300. Relational Income Statement Input interface 300 may comprise a display window or other software generated device that enables a user to input data, risk drivers, and other inputs into the system. For example, a user may type, select, or otherwise input values for certain parameters using interface 300. As discussed herein, certain risk drivers may be manipulated to enable evaluation of potential risk and return.

The interface 300 shown in FIG. 3 relates to an example designed to evaluate the risk and return of a fixed guaranteed investment contract (GIC) product. Different interfaces 300 may be used for other products.

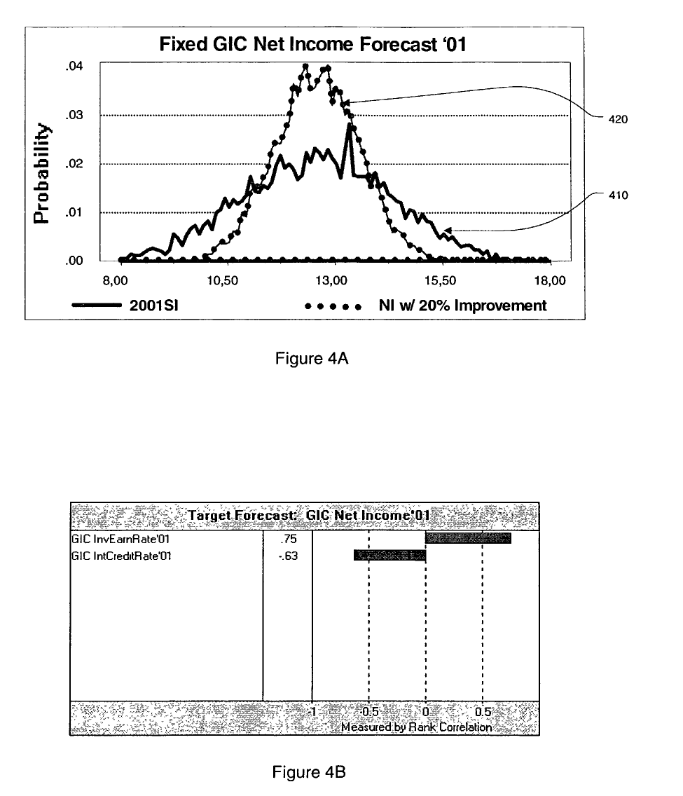

FIGS. 4A and 4B are examples of possible output from a simulation of an evaluation of the risks and return for a GIC according to one embodiment of the invention. Output may comprise graphs, charts, equations, relationship matrices or other visual, textual, or pictographic displays that aid in the evaluation and interpretation of the processed data. For example, in FIG. 4A, line 410 shows the various probabilities associated with varying the input factors from low to high and the inter-relationship within the input factors. Line 420 shows the effect of reducing the variation on input factors and their effect on the output.

FIG. 4B is an example of a sensitivity chart showing the affect of individual risk drivers on the forecast net income for a GIC according to one embodiment of the invention. This chart indicates that, in this example, the earned rate is positively correlated to the output and is more sensitive by 0.10 then the crediting rate to improve the output.

Some embodiments of the invention include features that enable a user to evaluate the risks and return for combinations or groupings of particular products, companies, divisions, or other composite entities. For example, a parent company may want to evaluate the affect of certain risk factors associated with each of its subsidiary divisions or a company may wish to evaluate the affect of introducing a new product into an existing portfolio of products.

For example, by developing relational income statements and through simulation, input factors (risk drivers) are able to affect either individual product or any higher hierarchical level. This is because the relational income statements are interconnected and the risk factors are aggregated to see the higher order product effect.

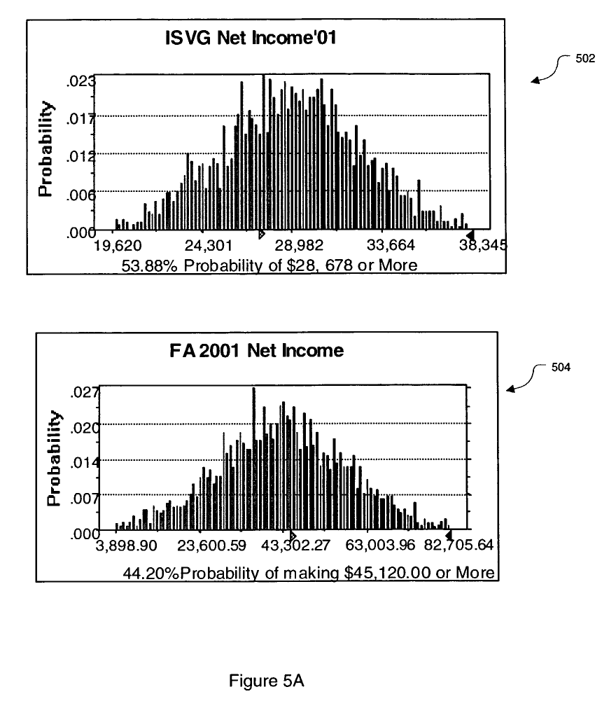

FIG. 5A is an example of two output displays for two separate products that may serve as input for a company wide evaluation of risks and return according to embodiments of the invention. FIG. 5B is an example of an output display showing combined affects on company net income for the two products shown in FIG. 5A. As shown in FIG. 5A an evaluation of an Institutional Stable Value Group (ISVG) product may produce an output display 502. Similarly, an evaluation of a Fixed Annuity (FA) product may result in an output display 504. Combining output displays 502 and 504 may result in a combined display 506 that enables evaluation of overall company performance with respect to the two products.

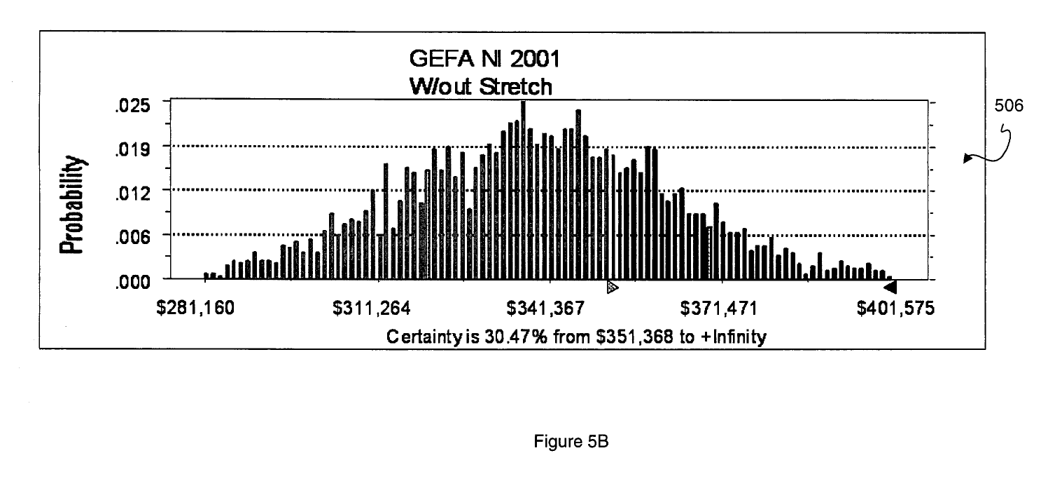

FIG. 6 is an example of another possible output display according to embodiments of the invention. As discussed herein, the invention may incorporate any number of output displays to aid in evaluating a particular risk return scenario. FIG. 6 shows an example of a tornado chart display for a number of products. The tornado chart shows the various input factors (Left Hand Column) risk drivers affect on the overall company output. These effects are ranked from highest to lowest and the magnitude each input driver as measured by the range or volatility on the output. One feature of a tornado chart display is that it enables a user to identify those risk drivers that have the highest impact on the outcome (e.g., net income) and allow prioritization of those risk drivers.

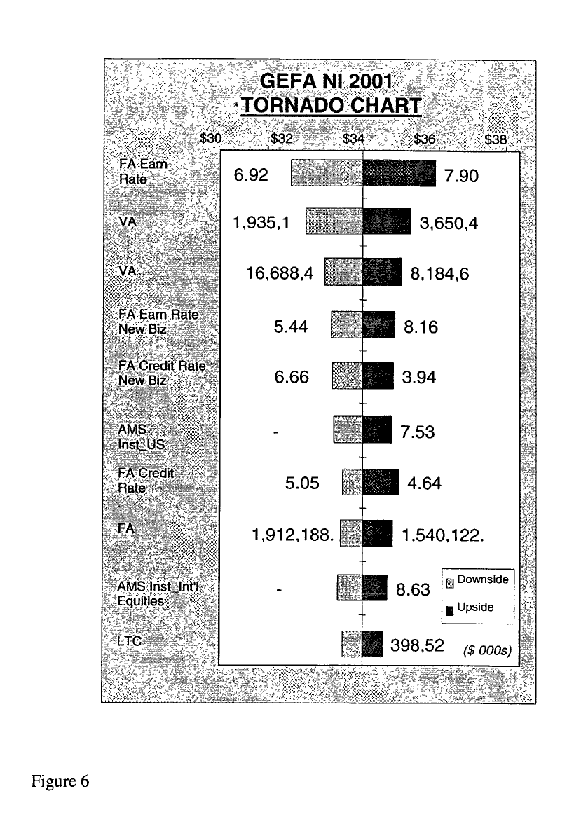

The following example applications of the invention are provided to illustrate some features of the invention. The first example application relates to an insurance company selling a term life insurance product. The insurance company would like to evaluate the affect of a change in retention limits for the product. Following method outlined in FIG. 2, the company first determines a forecast model. In this case, the company determines that a 95% confidence interval, steady state forecast model is applicable. The risk driver for this example were the standard drivers for term insurance (Mortality, interest spread, new production, renewal, lapse rate) the change was to increase revenue according to less reinsurance cost. A simulation is run using the data for prior periods (e.g., the last two years, etc.). FIG. 7 is an example of an output display for the simulation. As shown in FIG. 7, the affect of the risk driver retention limit results in a net income for the term insurance product of $2 million. The increase is because the volatility does not increase while keeping more of the premium received. Had the volatility increased, the amount of off-setting premium kept may not be sufficient to off-set the volatility increase.

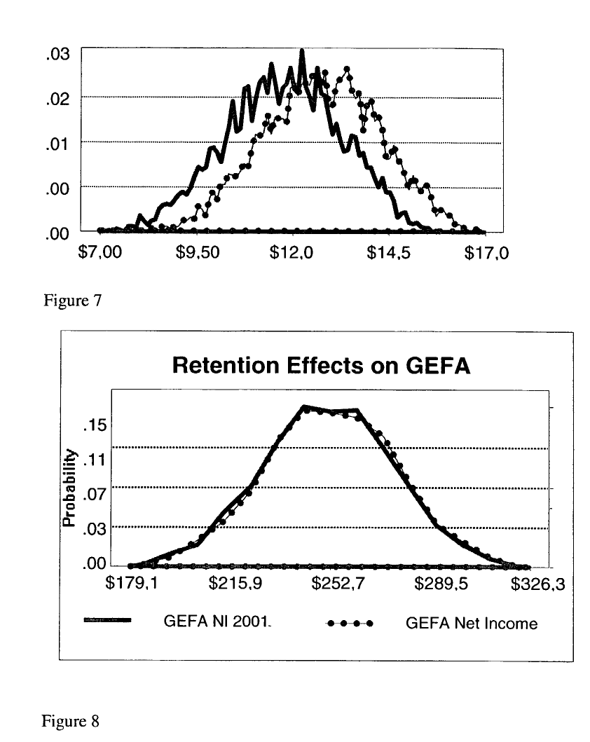

This example can be further extended to determine the affect of the retention limit risk driver on the overall company net income. FIG. 8 is an example of a display output that incorporates the retention limit risk driver calculation into the net income projection for the insurance company.

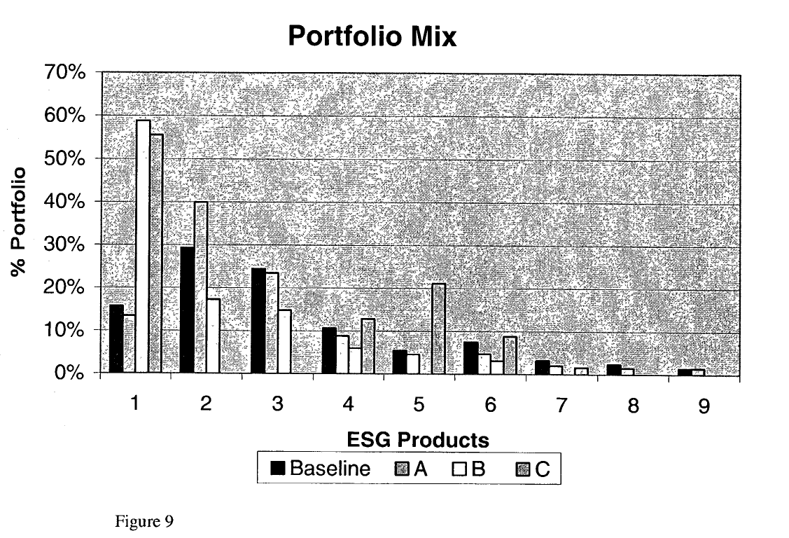

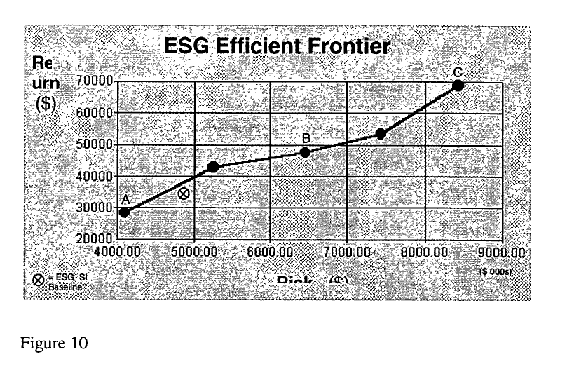

Another application of the invention is to enable an evaluation of investment portfolio products to optimize investment options. FIG. 9 is an example of different portfolio mixes for products A, B and C. In some embodiments, optimizing investment options may be performed by modeling individual investment returns and the capital required to support the present return structure. Once an individual return is modeled, the output from the model in the form of ROE (return on equity) is converted into input and with the Simplex Methodology, an efficient frontier is established. This frontier has the associated product mix and proportions that will produce higher returns with less volatility. This is shown in FIG. 10 as the efficient frontier line moves from the lower left hand corner (A) to the upper right hand corner(C).

According to another embodiment of the invention, a computer-usable and writeable medium having a plurality of computer readable program code stored therein may be provided for practicing the process of the present invention. The process and system of the present invention may be implemented within a variety of operating systems, such as a Windows® operating system, various versions of a Unix-based operating system (e.g., a Hewlett Packard, a Red Hat, or a Linux version of a Unix-based operating system), or various versions of an AS/400-based operating system. For example, the computer-usable and writeable medium may be comprised of a CD ROM, a floppy disk, a hard disk, or any other computer-usable medium. One or more of the components of the system may comprise computer readable program code in the form of functional instructions stored in the computer-usable medium such that when the computer-usable medium is installed on the system, those components cause the system to perform the functions described. The computer readable program code for the present invention may also be bundled with other computer readable program software.

Additionally, various entities and combinations of entities may employ a computer to implement the components performing the above-described functions. According to an embodiment of the invention, the computer may be a standard computer comprising an input device, an output device, a processor device, and a data storage device. According to other embodiments of the invention, various components may be computers in different departments within the same corporation or entity. Other computer configurations may also be used. According to another embodiment of the invention, various components may be separate entities such as corporations or limited liability companies. Other embodiments, in compliance with applicable laws and regulations, may also be used.

Other embodiments, uses and advantages of the present invention will be apparent to those skilled in the art from consideration of the specification and practice of the invention disclosed herein. The specification and examples should be considered exemplary only. The intended scope of the invention is only limited by the claims appended hereto.

We claim:

1. A processor implemented method for evaluating risk and return, the method comprising:
determining one or more risk drivers;
determining a forecast model based, at least in part, upon the one or more risk drivers;
enabling a processor to run a simulation using the forecast model and the one or more risk drivers; and
generating one or more output displays that enable an evaluation of risk and return based, at least in part, upon the simulation.

2. The method of claim 1 wherein the one or more risk drivers are selected from the group consisting essentially of:
lapse rate of an insurance policy, mortality rate of insurance policy holders, morbidity rate of insurance policy holders, production rates, or insurance premiums.

3. The method of claim 1 wherein the one or more risk drivers are selected from the group consisting essentially of:
quantifications of volatility, rates of return on investments, termination rates, loss ratios, spreads, competition rates, first year premiums, renewal premiums, inflows, outflows, market appreciation/depreciation, credit rate risks or default risk.

4. The method of claim 1 wherein the simulation is a Monte Carlo simulation.

5. The method of claim 1 wherein the simulation is a Quasi Monte Carlo simulation.

6. The method of claim 1 wherein the simulation is a quantile regression simulation.

7. A processor based system for evaluating risk and return, the system comprising:
a risk driver input module for enabling input relating to one or more risk drivers;
a forecast module input module for accepting input relating to a forecast model wherein the forecast model is based, at least in part, upon the one or more risk drivers;
a simulation module for running a simulation using the forecast model and the one or more risk drivers; and
an output display module for generating one or more output displays that enable an evaluation of risk and return based, at least in part, upon the simulation.

8. The system of claim 7 wherein the simulation is a Monte Carlo simulation.

9. The system of claim 7 wherein the simulation is a Quasi Monte Carlo simulation.

10. The system of claim 7 wherein the simulation is a quantile regression simulation.
